(19) United States
(12) Patent Application Publication
(10) Pub. No.: US 2011/0233536 A1
(43) Pub. Date: Sep. 29, 2011

(54) THIN FILM TRANSISTOR ARRAY PANEL AND METHOD OF FABRICATING THE SAME

(75) Inventors: Young-Min KIM, Yongin-si (KR); Yeon-Taek JEONG, Suwon-si (KR); Seon-Pil JANG, Seoul (KR); Seung-Hwan CHO, Suwon-si (KR); Bo-Sung KIM, Seoul (KR); Tae-Young CHOI, Seoul (KR)

(73) Assignee: SAMSUNG ELECTRONICS CO., LTD., Suwon-si (KR)

(21) Appl. No.: 12/839,705

(22) Filed: Jul. 20, 2010

(30) Foreign Application Priority Data
Mar. 24, 2010 (KR) 10-2010-0026313

(51) Int. Cl. H01L 29/786; H01L 21/368

(52) U.S. Cl. 257/43; 438/104; 257/E29.296; 257/E21.464

(57) ABSTRACT

A thin film transistor array panel including an oxide semiconductor layer realizing excellent stability and electrical characteristics and an easy method of manufacturing the same are provided. A thin film transistor array panel includes: a substrate; an oxide semiconductor layer disposed on the substrate and including a metal oxide selected from the group consisting of zinc oxide, tin oxide, and hafnium oxide; a gate electrode overlapping the oxide semiconductor layer; a gate insulating film disposed between the oxide semiconductor layer and the gate electrode; and a source electrode and a drain electrode disposed to at least partially overlap the oxide semiconductor layer and separated from each other.

### CROSS-REFERENCE TO RELATED APPLICATION

This application claims priority to and the benefit of Korean Patent Application No. 10-2010-0026313 filed in the Korean Intellectual Property Office on Mar. 24, 2010, the entire contents of which are incorporated herein by reference.

### BACKGROUND OF THE INVENTION

(a) Field of the Invention

The present invention relate to a thin film transistor array panel and a method of fabricating the same. More particularly, the present invention relates to a thin film transistor array panel including an oxide semiconductor layer, which has superior stability and electrical characteristics and that can be easily manufactured, and a method of fabricating the thin film is transistor array panel.

(b) Description of the Related Art

Liquid crystal displays (LCDs) are one of the most widely used types of flat panel displays. Generally, an LCD includes a pair of display panels having electrodes and a liquid crystal layer interposed between the display panels. In the LCD, voltages are applied to the electrodes to generate an electric field. The electric field determines the alignment of liquid crystal molecules of the liquid crystal layer, thereby controlling polarization of incident light. As a result, a desired image is displayed on the LCD.

Generally, the LCD includes a thin film transistor for switching each pixel. A thin film transistor is a switching device including, as its three terminals, a gate electrode, which receives a switching signal, a source electrode, which receives a data voltage, and a drain electrode, which outputs the data voltage. The thin film transistor further includes an active layer between the gate electrode and the source and drain electrodes, and the active layer is usually made of amorphous silicon. As the size of display becomes larger, it is required to develop thin film transistors having higher electron mobility.

Particularly, the electron mobility in the active layer needs to be high. However, the active layer made of amorphous silicon has electron mobility of about 0.5 cm²/V·s, which is becoming non-applicable to transistors requiring a higher driving speed. Also, the semiconductor materials used in the active layer are manufactured by vacuum-based depositing instruments such as through CVD, sputtering, etc., which are expensive. Therefore, it may be desirable to develop a thin film transistor that has higher electron mobility. Also, it may be desirable to develop a semiconductor material that can be easily manufactured by a solution method that is possible to apply to a low temperature and low pressure coating process or printing process.

The above information disclosed in this Background section is only for enhancement of understanding of the background of the invention and therefore it may contain information that does not form the prior art that is already known in this country to a person of ordinary skill in the art.

### SUMMARY OF THE INVENTION

Exemplary embodiments of the present invention provide a thin film transistor array panel including an oxide semiconductor layer that may have high electron mobility and that can be manufactured by a solution method.

Exemplary embodiments of the present invention provide a thin film transistor array panel including an oxide semiconductor layer that has superior stability and electrical characteristics and that can be easily manufactured.

Exemplary embodiments of the present invention also provide a method of fabricating a thin film transistor array panel including an oxide semiconductor layer that has superior stability and electrical characteristics and that can be easily manufactured.

Additional features of the invention will be set forth in the description which follows, and in part will be apparent from the description, or may be learned by practice of the invention.

An exemplary embodiment of the present invention discloses a thin film transistor array panel including an insulating substrate. An oxide semiconductor layer is formed on the insulating substrate and includes at least one metal oxide selected from zinc oxide, tin oxide, and hafnium oxide, a gate electrode overlaps the oxide semiconductor layer, a gate insulating film is interposed between the oxide semiconductor layer and the gate electrode, and a source electrode and a drain electrode at least partially overlap the oxide semiconductor layer and are separated from each other.

An exemplary embodiment of the present invention also discloses a method of fabricating a thin film transistor array panel. The method includes: preparing a metal compound solution including a metal inorganic salt and a solvent, the metal inorganic salt including at least one of a zinc inorganic salt, a tin inorganic salt, and a hafnium inorganic salt; coating the metal compound solution on a substrate; and heat-treating the metal compound solution.

It is to be understood that both the foregoing general description and the following detailed description are exemplary and explanatory and are intended to provide further explanation of the invention as claimed.

The thin film transistor array panel according to the present invention includes the metal oxide semiconductor layer as the channel layer such that the electron mobility is high in the channel layer, thereby realizing high speed driving.

Also, the manufacturing method of the thin film transistor array panel according to the present invention uses the solution that is capable of realizing the low temperature and low pressure process, and thereby the manufacturing cost may be reduced and the stability and excellent electrical characteristics may be obtained.

### BRIEF DESCRIPTION OF THE DRAWINGS

FIG. 1 is a cross-sectional view of a thin film transistor array panel according to a first exemplary embodiment of the present invention.

FIG. 2 is a cross-sectional view of a thin film transistor array panel according to a second exemplary embodiment of the present invention.

FIG. 3 is a flow chart illustrating a method of fabricating an oxide semiconductor of a thin film transistor array panel according to an exemplary embodiment of the present invention.

FIG. 4 is a graph illustrating a transfer curve of the thin film transistor including the oxide semiconductor layer.

### DETAILED DESCRIPTION OF THE EMBODIMENTS

Advantages and features of the present invention and methods of accomplishing the same may be understood more readily by reference to the following detailed description of exemplary embodiments and the accompanying drawings. The present invention may, however, be embodied in many different forms and should not be construed as being limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity.

It will be understood that when an element such as a layer, film, region, or substrate is referred to as being “on” another element, it can be directly on the other element or intervening elements may also be present. In contrast, when an element is referred to as being “directly on” another element, there are no intervening elements present. The term “and/or” includes each of the mentioned items and all combinations of at least one. The spatially relative terms “below”, “beneath”, “lower”, “above”, and “upper” may be used to easily describe a correlation between one element or constituent element and other elements or constituent elements as shown in the accompanying drawings. The spatially relative terms should be understood as terms including directions shown in the drawings in addition to different orientations of elements in use or operation. The same reference numerals designate the same elements throughout the specification.

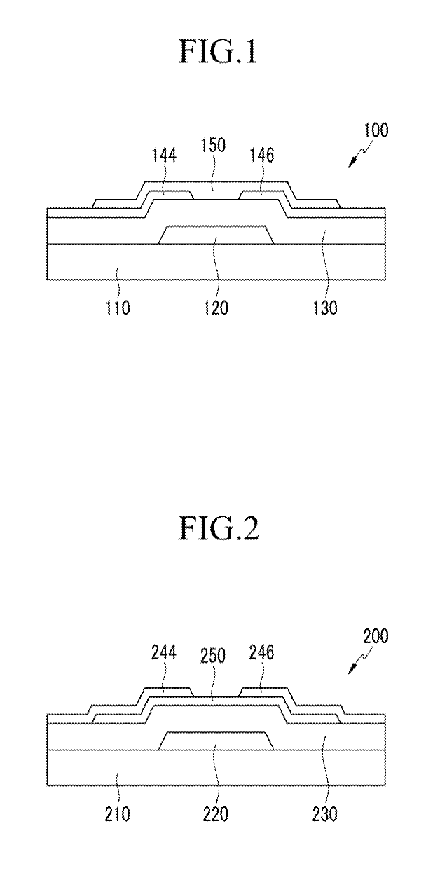

Hereinafter, a thin film transistor array panel according to a first exemplary embodiment of the present invention will be described in detail with reference to FIG. 1. FIG. 1 is a cross-sectional view of the thin film transistor array panel according to a first exemplary embodiment of the present invention. Referring to FIG. 1, the thin film transistor array panel includes an insulating substrate 110, a gate electrode 120, a gate insulating film 130, a source electrode 144, a drain electrode 146, and an oxide semiconductor layer 150. The insulating substrate 110 may include a glass substrate or a plastic substrate. The gate electrode 120, which is a part of gate wiring that transmits a gate signal, is formed on the insulating substrate 110.

The gate wiring including the gate electrode 120 may be made of an aluminum (Al)-based metal such as aluminum and an aluminum alloy, a silver (Ag)-based metal such as silver and a silver alloy, a copper (Cu)-based metal such as copper and a copper alloy, a molybdenum (Mo)-based metal such as molybdenum and a molybdenum alloy, chromium (Cr), titanium (Ti), or tantalum (Ta).

In addition, the gate wiring including the gate electrode 120 may have a multi-film structure composed of two conductive films (not shown) with different physical characteristics. One of the two conductive films may be made of a metal with low resistivity, such as an aluminum-based metal, a silver-based metal, or a copper-based metal, in order to reduce a signal delay or a voltage drop of the gate wiring. The other of the conductive films may be made of a different material, in particular, a material having superior contact characteristics with indium tin oxide (ITO) and indium zinc oxide (IZO), such as a molybdenum-based metal, is chromium, titanium, or tantalum.

Examples of multi-film structures include a chromium lower film and an aluminum upper film, an aluminum lower film and a molybdenum upper film, or a titanium lower film and a copper upper film. However, the present invention is not limited thereto, and the gate wiring may be formed of various metals and conductors.

A gate insulating film 130 is formed on the insulating substrate 110 and the gate wiring including the gate electrode 120. The gate insulating film 130 may be made of silicon oxide (SiOx), silicon nitride (SiNx), or silicon oxynitride (SiON). The gate insulating film 130 may have a multi-layered structure of silicon nitride and silicon oxide. In this case, a silicon nitride layer may be formed on the insulating substrate 110 and a silicon oxide layer may be formed on the silicon nitride layer, and thereby the silicon oxide layer may contact the oxide semiconductor layer 150. In the case of using the silicon oxynitride layer as the gate insulating layer 130, the oxygen content in the silicon oxynitride layer may have a concentration gradient. Specifically, the oxygen content in the gate insulating film 130 may become higher closer to the oxide semiconductor layer 150. As the oxide semiconductor layer 150 and the silicon oxide layer directly contact, it is possible to prevent deterioration of the channel layer by constantly maintaining the concentration of oxygen deficiency in the oxide semiconductor layer 150.

The source electrode 144 and the drain electrode 146 are a part of data wiring that transmits data signals. The source electrode 144 and the drain electrode 146 are disposed on the gate insulating film 130.

In addition, the oxide semiconductor layer 150 is disposed on the source electrode 144 and the drain electrode 146. A passivation layer (not shown) may be disposed on the oxide semiconductor layer 150. In this exemplary embodiment, the gate electrode 120, the gate insulating film 130, the source electrode 144, and the drain electrode 146 are placed in order, but the order in which they are disposed or positions at which they are located in the oxide thin film transistor may vary. The source electrode 144 and the drain electrode 146 are formed spaced apart from each other. At least a part thereof overlaps the oxide semiconductor layer 150.

In addition, the drain electrode 146 faces the source electrode 144 with respect to the channel region of the oxide thin film transistor, and at least a part of the drain electrode 146 overlaps the oxide semiconductor layer 150. The source electrode 144 and the drain electrode 146 may be formed with a material forming an ohmic contact with the oxide semiconductor layer 150 when directly contacting the oxide semiconductor layer 150.

For example, if the data wiring (i.e. the source electrode 144 and the drain electrode 146) is made of a material having a lower work function than that of the material of the oxide semiconductor layer 150, an ohmic contact can be formed between the two layers.

On the other hand, an ohmic contact layer (not shown) may be included between the region where the source electrode 144 and drain electrode 146 and the oxide semiconductor layer 150 overlap. The ohmic contact layer functions to form the ohmic contact.

The source electrode 144 and drain electrode 146 may be made of an aluminum (Al)-based metal such as aluminum and an aluminum alloy, a silver (Ag)-based metal such as silver and a silver alloy, a copper (Cu)-based metal such as copper and a copper alloy, a molybdenum (Mo)-based metal such as molybdenum and a molybdenum alloy, chromium (Cr), titanium (Ti), or tantalum (Ta), like the gate electrode 120. Also, they may be made of a transparent conductive material such as ZnO, indium tin oxide (ITO), and indium zinc oxide (IZO).

Also, the data wire may have the multi-layered structure including the two conductive layers (not shown) with different physical characteristics, and exemplary combinations may be a double layer such as Mo(Mo alloy)/Al(Al alloy), Ti(Ti alloy)/Al(Al alloy), Ta(Ta alloy)/Al(Al alloy), Ni(Ni alloy)/Al(Al alloy), Co(Co alloy)/Al(Al alloy), Ti(Ti alloy)/Cu(Cu alloy), and Cu(Cu alloy)/Mn(Mn alloy), or a triple layer such as Ti(Ti alloy)/Al(Al alloy)/Ti(Ti alloy), Ta(Ta alloy)/Al(Al alloy)/Ta(Ta alloy), Ti(Ti alloy)/Al(Al alloy)/TiN, Ta(Ta alloy)/Al(Al alloy)/TaN, Ni(Ni alloy)/Al(Al alloy)/Ni(Ni alloy), Co(Co alloy)/Al(Al alloy)/Co(Co alloy), and Mo(Mo alloy)/Al(Al alloy)/Mo(Mo alloy).

Particularly, when the data wire is made of Cu or a Cu alloy, there is no problem in the ohmic contact characteristic between the data wire and the pixel electrode (not shown) such that the double layer including the layer including Mo, Ti, or Ta may be applied between the layer including Cu or Cu alloy and the oxide semiconductor layer 150 as the data wire.

However, the present invention is not limited thereto, and the source electrode 144 and the drain electrode 146 may be formed of various metals and conductors. The drain electrode 146 may be electrically connected to the pixel electrode (not shown), and an electric field may be formed by a voltage applied to the pixel electrode, thereby realizing the display of the gray according to the electric field.

An oxide semiconductor layer 150 including a metal oxide is formed on the source electrode 144 and the drain electrode 146. The oxide semiconductor layer 150 may further include a metal inorganic salt. The oxide semiconductor layer 150 overlaps the gate electrode 120. The gate insulating layer 130 and the source electrode 144 and the drain electrode 146 are disposed between the oxide semiconductor layer 150 and the gate electrode 120.

The metal inorganic salt may contain at least one metal positive ion selected from group including lithium (Li), sodium (Na), potassium (K), rubidium (Rb), cesium (Cs), beryllium (Be), aluminum (Al), barium (Ba), magnesium(Mg), calcium (Ca), strontium (Sr), titanium (Ti), zirconium (Zr), hafnium (Hf), vanadium (V), yttrium (Y), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), gallium (Ga), indium (In), thallium (Tl), silicon (Si), germanium (Ge), lead (Pb), phosphorus (P), arsenic (As), lanthanum (La), cerium (Ce), gadolinium (Gd), neodymium (Nd), tellurium (Te), scandium (Sc), polonium (Po), praseodymium (Pr), terbium (Tb), dysprosium (Dy), holmium (Ho), europium (Eu), erbium (Er), ytterbium (Yb), antimony (Sb), bismuth (Bi), Zinc (Zn), Tin (Sn), and hafnium (Hf).

The metal inorganic salt may contain at least one anion selected from the group including hydroxide, acetate, propionate, acetylacetonate, 2,2,6,6-tetramethyl-3,5-heptanedionate, methoxide, sec-butoxide, t-butoxide, n-propoxide, i-propoxide, ethoxide, phosphate, alkylphosphonate, nitrate, perchlorate, sulfate, alkylsulfonate, phenoxide, fluoride, bromide, iodide, and chloride. The oxide semiconductor layer 150 is formed by coating the metal compound solution including the metal inorganic salt and a solvent, and then heat-treating the coated metal compound solution.

The metal compound solution may further include a stabilizer. The metal positive ion is combined with oxygen in the heat-treating while the metal inorganic salt and the solvent are hydrolyzed such that the metal oxide thin film consisting of the oxide semiconductor layer 150 is formed. In this case, the metal positive ion and/or negative ion of the inorganic salt included in the metal compound solution remain in the oxide semiconductor layer 150 and may be included. The metal positive ion and the negative ion of the inorganic salt may be included in the oxide semiconductor layer 150 as a combination type or a complex type that are combined to the solvent.

A stabilizer may also be contained in the metal compound solution. The stabilizer may contain at least one of diketone, amino alcohol, and polyamine. The solvent includes at least one selected from the group including water, tetrahydrofuran (THF), ether, and alcohol. On the other hand, although not shown, a passivation layer may be disposed on the oxide semiconductor layer 150. The passivation layer may have multi-layered structure in which silicon oxide (SiOx) and silicon nitride (SiNx) are deposited, and a silicon oxide (SiOx) layer contacts the oxide semiconductor layer 150 such that degradation of the channel layer may be prevented.

Next, another exemplary embodiment of the present invention will be described with reference to FIG. 2. FIG. 2 is a cross-sectional view of a thin film transistor array panel according to a second exemplary embodiment of the present invention. Referring to FIG. 2, a thin film transistor array panel 200 includes an insulation substrate 210, a gate electrode 220, a gate insulating layer 230, a source electrode 244, a drain electrode 246, and an oxide semiconductor layer 250. The gate electrode 220, which is a part of gate wiring that transmits a gate signal, is formed on the insulating substrate 210. A gate insulating film 230 is formed on the insulating substrate 210 and the gate electrode 220.

An oxide semiconductor layer 250 overlapping the gate electrode 220 is disposed on the gate insulating layer 230. The source electrode 244 and the drain electrode 246 are disposed on the oxide semiconductor layer 250. The source electrode 244 and the drain electrode 246 are formed spaced apart from each other, and at least a part thereof overlaps the oxide semiconductor layer 150. That is, the oxide semiconductor layer 250 is disposed between the gate insulating layer 230, and the source electrode 244 and drain electrode 246.

A passivation layer (not shown) including a silicon oxide layer may be disposed on the source electrode 244 and the drain electrode 246. The detailed description of the insulation substrate 210, the gate electrode 220, the gate insulating layer 230, the source electrode 244, the drain electrode 246, and the oxide semiconductor layer 250 as the constituent elements of the present exemplary embodiment is the same as that of the above exemplary embodiment such that it is omitted.

In the above-described exemplary embodiments, a bottom gate structure in which the gate electrode is disposed under the oxide semiconductor layer is described, however the present invention is not limited thereto and may be applied to a top gate structure in which the gate electrode is disposed on the oxide semiconductor layer.

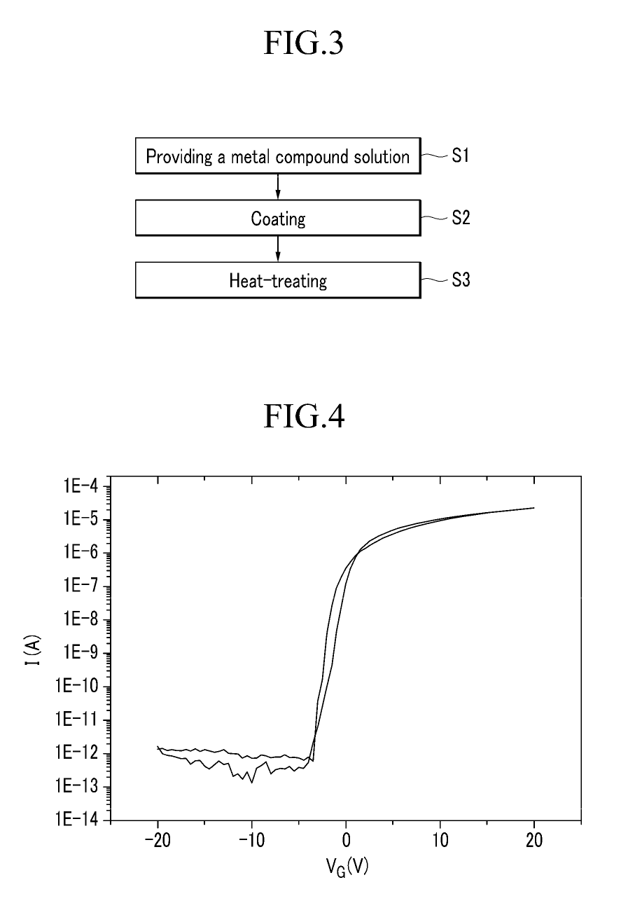

Hereinafter, a method for manufacturing the thin film transistor array panel of the present invention will be described. FIG. 3 is a flow chart illustrating a method of fabricating an oxide semiconductor of a thin film transistor array panel according to an exemplary embodiment of the present invention, and particularly a manufacturing method of an oxide semiconductor layer in the thin film transistor array panel.

A manufacturing method of a thin film transistor array panel according to an exemplary embodiment of the present invention includes providing a metal compound solution including a metal inorganic salt including a zinc inorganic salt and a tin inorganic salt and a solvent (S1), coating the metal compound solution on a substrate (S2), and heat-treating the metal compound solution (S3). In the providing of the metal compound solution (S1), the zinc inorganic salt and the tin inorganic salt are added and stirred in a predetermined solvent. Here, a third metal inorganic salt may be further included as well as the zinc inorganic salt and the tin inorganic salt.

According to the composition of the metal oxide thin film, the concentration of the zinc inorganic salt, the tin inorganic salt, and the third metal inorganic salt may be controlled in the solvent.

The metal inorganic salt may be a compound in which the metal positive ion and negative ion are combined.

The metal positive ion may be at least one selected from the group including lithium (Li), sodium (Na), potassium (K), rubidium (Rb), cesium (Cs), beryllium (Be), aluminum (Al), barium (Ba), magnesium (Mg), calcium (Ca), strontium (Sr), titanium (Ti), zirconium (Zr), hafnium (Hf), vanadium (V), yttrium (Y), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), gallium (Ga), indium (In), thallium (Tl), silicon (Si), germanium (Ge), lead (Pb), phosphorus (P), arsenic (As), lanthanum (La), cerium (Ce), gadolinium (Gd), neodymium (Nd), tellurium (Te), scandium (Sc), polonium (Po), praseodymium (Pr), terbium (Tb), dysprosium (Dy), holmium (Ho), europium (Eu), erbium (Er), ytterbium (Yb), antimony (Sb), bismuth (Bi), and hafnium (Hf).

The negative ion may be at least one selected from the group including hydroxide, acetate, propionate, acetylacetonate, 2,2,6,6-tetramethyl-3,5-heptanedionate, methoxide, sec-butoxide, t-butoxide, n-propoxide, i-propoxide, ethoxide, phosphate, alkylphosphonate, nitrate, perchlorate, sulfate, alkylsulfonate, phenoxide, fluoride, bromide, iodide, and chloride. Also, the metal inorganic salt may be at least one selected from the group including zinc(II) acetate, tin(II) chloride, and hafnium(IV) chloride.

For example, the composition of the oxide semiconductor layer manufactured when zinc(II) acetate, tin(II) chloride, and hafnium(IV) chloride are all used as the metal inorganic salt becomes HfZnSnO.

A metal inorganic salt of a different kind is used according to necessity such that the composition of the oxide semiconductor layer may be changed and it is possible to apply doping of other element. A stabilizer may also be contained in the metal compound solution, and the stabilizer may contain at least one of diketone, amino alcohol, and polyamine. In detail, the diketone may include acetylacetone. Amino alcohol may include at least one selected from the group including ethanolamine, diethanolamine, and triethanolamine.

For example, the amino alcohol may contain any one of AgNO3, CH5NO.HCl, C2H7NO, C2H7NO.HCl, C2H8N2O, C3H9NO, C3H9NO2, C3H9NO2.HCl, C3H10N2O, C4H6F3NO2, C4H9NO2, C4H11NO, C4H11NO2, C4H11NO2.HCl, C4H11NO3, C4H11NS.HCl, C4H12N2O.2HCl, C4H12N2O, C4H12N2O2.2HCl, C5H8F3NO2, C5H11NO.HCl, C5H11NO2, C5H13NO, C5H13NO2, C5H14N2O, C6H10F3NO2, C6H11NO3, C6H13NO, C6H13NO.HCl, C6H15NO, C6H15NO2, C6H15NO3, C6H16N2O2, C7H8ClNO, C7H9NO, C7H9NO2.HBr, C7H10N2O.2HCl, C7H12F3NO2, C7H13NO3, C7H15NO.HCl, C7H15NO3, C7H17NO, C7H17NO2, C7H18N2O, C8H9ClN2O3, C8H11NO, C8H11NO2.HCl, C8H11NO2, C8H11NO2.HBr, C8H11NO2.HCl, C8H11NO3.HCl, C8H11NO3.HBr, C8H11N3O3, C8H14F3NO2, C8H15NO, C8H15NO3, C8H17NO4, C8H19NO, C8H19NO2, C9H12ClNO, C9H13NO, C9H13NO2, C9H13NO2.HCl, C9H17NO3, C9H19NO3, C10H13NO3, C10H15NO, C10H15NO.HCl, C10H15NO, C10H15NO2, C10H16N2O.H2SO4.H2O, C10H17NO, C10H19NO3, C10H21NO3, C10H23NO, C11H15NO3, C11H15NO4, C11H17NO, C11H17NO.HCl, C11H17NO2, C11H17NO3.HCl, C11H20N2O5S, C11H21NO3, C12H17NO3, C12H19N3O5, C13H20N2O4, C13H31NO5Si, C14H19NO3, C14H19N3O.C6H8O7, C14H21NO3, C15H12F6N2O2, C15H33NO6, C16H25NO.HBr, C17H17NO3, C17H21NO, C17H22N2O, C18H19NO3, C19H21NO4, C20H23NO3, C25H29NO8S3, C27H30N6O, and C27H32Cl2N2O4.

The polyamine may contain ethylenediamine or 1,4-diaminobutane. For example, polyamine may contain any one of C2H8N2, C3H10N2, C4H12N2, C5H14N2, C5H15N3.3HCl, C5H15N3, C5H16N2S1, C6H6Cl2N2, C6H7BrN2, C6H7ClN2, C6H7N3O2, C6H8N2, C6H12N4, C6H14N2, C6H16N2, C6H17N3, C6H18ClN3Si, C6H18N4, C6H18N4.xH2O, C7H6BrF3N2, C7H7F3N2, C7H9FN2, C7H10N2, C7H18N2, C7H19N3, C7H20N4, C8H10N2O2, C8H12N2, C8H20N2, C8H20N2O, C8H21N3, C8H22N4, C8H23N5, C9H14N2, C9H14N2O2S, C9H2ON2, C9H22N2, C9H22N2O, C9H23N3, C9H24N4, C10H10N2, C10H16N2, C10H22N2, C10H24N2, C10H24N2O3, C10H25N3, C10H28N6, C11H18N2, C11H18N2O, C11H22N2O2, C11H26N2, C12H11ClN2, C12H12N2, C12H12N2O, C12H14N4, C12H28N2, C12H29N3, C12H30N4, C13H12N2, C13H14N2, C13H26N2, C14H18N2, C14H22N2, C14H32N2, C15H30N2, C15H35N3, C15H36N4, C16H20N2, C17H22N2, C18H31N, C20H16N2, C22H48N2, C22H49N3, C25H20N2, C26H38N4, C26H40N2, C29H30N2, and C29H46N2.

The solvent of the metal compound solution includes at least one selected from the group including water, tetrahydrofuran (THF), ether, and alcohol.

Next, the coating of the metal compound solution on the substrate (S2) is executed. The substrate may be a thin film transistor array panel in which the channel layer is not formed. That is, the substrate may be a substrate including the gate electrode, the gate insulating layer, and the source electrode and drain electrode that are formed on the insulation substrate.

Also, the substrate may be an insulating substrate on which the gate electrode and the gate insulating layer are formed. The present invention is not limited thereto, however the structure of the substrate may be changed according to the structure of the thin film transistor that will be manufactured.

The coating (S2) may be one of spin coating, dip coating, bar coating, screen printing, slide coating, roll coating, spray coating, slot coating, dip-pen, inkjet, and nano-dispensing methods.

Next, the heat-treating of the substrate coated with the metal compound solution (S3) is executed. The heat-treating is proceeded at a temperature in the range of about 100° C. to 500° C. More preferably, it is executed in a temperature range of less than 300° C. When the heat-treating temperature is less than 100° C., the formation of the metal oxide is not smooth and the manufactured oxide semiconductor layer may not function as the channel layer of the thin film transistor. When the heat-treating temperature is more than 500° C., the heat-treating temperature is over the temperature range that is used in the entire process of the thin film transistor array panel and the merit of the low temperature process is lost.

By executing the heat-treating (S3), the various additives such as the solvent of the metal compound solution and the stabilizer are removed, thereby forming the metal oxide thin film. The metal inorganic salt and the solvent are hydrolyzed such that the oxide semiconductor layer including the metal oxide is formed. In this case, the metal inorganic salt may be partially included in the metal oxide thin film.

After the heat-treating (S3), the oxide semiconductor layer may be etched to leave a desired portion thereof. The etching of the oxide semiconductor layer may be undertaken with various methods (dry etching, wet etching, etc.). According to an exemplary embodiment, a photosensitive film is formed on the oxide semiconductor layer, the photosensitive film is exposed and developed by using a mask to form a predetermined pattern, and the oxide semiconductor layer is etched by using the patterned photosensitive film as a mask to form the desired pattern.

Next, the manufacturing method of the thin film transistor of the present invention will be described in detail through an exemplary embodiment, however the scope of the present invention is not limited by the exemplary embodiment.

### Exemplary Embodiment 1

Hafnium(IV) chloride at 0.0012 mol, zinc(II) acetate at 0.003 mol, and tin(II) chloride at 0.003 mol are added to a solvent of 2-methoxyethanol at 20 mL and acetylacetone at 0.012 mol as the stabilizer is added, and they are stirred for 6 hours to prepare a metal compound solution. The gate electrode of Mo metal, the gate insulating layer of silicon oxide, and the source and drain electrodes of ITO are formed and patterned on the glass substrate, and the metal compound solution is coated on the source and drain electrodes of ITO by spin coating. Next, the heat-treating is executed at temperature of about 450° C. for 30 minutes. The oxide thin film including HfZnSnO is formed through the heat-treating, and the thin film transistor including the oxide thin film as the channel layer is manufactured.

### Exemplary Embodiment 2

Hafnium(IV) chloride at 0.0012 mol, zinc(II) acetate at 0.003 mol, and tin(II) chloride at 0.003 mol are added to the solvent of 2-methoxyethanol at 20 mL and acetylacetone at 0.012 mol as a stabilizer is added, and they are stirred for 6 hours to prepare a metal compound solution. The gate electrode of Mo metal and the gate insulating layer of silicon oxide are formed and patterned on the glass substrate, and the metal compound solution is coated on the gate insulating layer by spin coating. Next, the heat-treating is executed at a temperature of about 450° C. for 30 minutes. The oxide thin film including HfZnSnO is formed through the heat-treating, and the source and drain electrodes of aluminum are deposited to manufacture the thin film transistor.

Characteristic Measuring

An I-V characteristic of the thin film transistor manufactured by the Exemplary Embodiment 1 is measured by using a semiconductor parameter analyzer such as an HP-4145B semiconductor characteristic analyzer. FIG. 4 is a graph illustrating a transfer curve of the thin film transistor manufactured by Exemplary Embodiment 1. A current (I) flowing through the oxide semiconductor layer including HfZnSnO according to the application of the gate voltage (V_{G}) is shown. In this case, the voltage between the source electrode and the drain electrode is determined as 10V (Vds=10V). FIG. 4 shows two curved lines, wherein one shows the current value measured while increasing the voltage and the other shows the current value measured while decreasing the voltage. Referring to FIG. 4, it may confirmed that the thin film transistor of the present invention has high saturation mobility of 3.70 cm2/Vs and a high on-off current ratio of more than 10E7, and the threshold voltage thereof is −2.12V thereby being operated as the depletion mode. Accordingly, the oxide semiconductor layer manufactured by the present exemplary embodiment has appropriate performance for forming the channel region of the thin film transistor (TFT).

While the present invention has been particularly shown and described with reference to exemplary embodiments thereof, it will be understood by those skilled in the art that various modifications and variations in form and detail may be made therein without departing from the spirit or scope of the invention. The exemplary embodiments should be considered in a descriptive sense only and not for purposes of limitation. Thus, it is intended that the present invention covers modifications and variations of this invention provided they come within the scope of the appended claims and their equivalents.

What is claimed is:

1. A thin film transistor array panel, comprising:
a substrate;
an oxide semiconductor layer disposed on the substrate and comprising at least one metal oxide selected from zinc oxide, tin oxide, and hafnium oxide;
a gate electrode overlapping the oxide semiconductor layer;
a gate insulating film disposed between the oxide semiconductor layer and the gate electrode; and
a source electrode and a drain electrode disposed to at least partially overlap the oxide semiconductor layer and separated from each other.

2. The panel of claim 1, wherein the oxide semiconductor layer is disposed on the source electrode and the drain electrode.

3. The panel of claim 1, wherein the oxide semiconductor layer is disposed between the gate insulating film and the source electrode and drain electrode.

4. The panel of claim 1, wherein the oxide semiconductor layer further comprises a metal inorganic salt.

5. The panel of claim 4, wherein the metal inorganic salt comprises at least one metal cation selected from lithium (Li), sodium (Na), potassium (K), rubidium (Rb), cesium (Cs), beryllium (Be), aluminum (Al), barium (Ba), magnesium (Mg), calcium (Ca), strontium (Sr), titanium (Ti), zirconium (Zr), vanadium (V), yttrium (Y), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), gallium (Ga), indium (In), thallium (Tl), silicon (Si), germanium (Ge), lead (Pb), phosphorus (P), arsenic (As), lanthanum (La), cerium (Ce), gadolinium (Gd), neodymium (Nd), tellurium (Te), scandium (Sc), polonium (Po), praseodymium (Pr), terbium (Tb), dysprosium (Dy), holmium (Ho), europium (Eu), erbium (Er), ytterbium (Yb), antimony (Sb), bismuth (Bi), zinc (Zn), tin (Sn), and hafnium (Hf).

6. The panel of claim 4, wherein the metal organic salt comprises at least one anion selected from hydroxide, acetate, propionate, acetylacetonate, 2,2,6,6-tetramethyl-3,5-heptanedionate, methoxide, sec-butoxide, t-butoxide, n-propoxide, i-propoxide, ethoxide, phosphate, alkylphosphonate, nitrate, perchlorate, sulfate, alkylsulfonate, phenoxide, fluoride, bromide, iodide and chloride.

7. The panel of claim 4, wherein the oxide semiconductor layer is a coated layer formed from coating a metal compound solution comprising the metal inorganic salt and a solvent.

8. The panel of claim 7, wherein the solvent comprises at least one of water, tetrahydrofuran (THF), ether and alcohol.

9. A method of fabricating a thin film transistor array panel, the method comprising:
preparing a metal compound solution comprising a metal inorganic salt and a solvent, the metal inorganic salt comprising at least one of zinc inorganic salt, tin inorganic salt and hafnium inorganic salt;
coating the metal compound solution on a substrate; and
heat-treating the metal compound solution.

10. The method of claim 9, wherein the metal inorganic salt comprises at least one metal cation selected from lithium (Li), sodium (Na), potassium (K), rubidium (Rb), cesium (Cs), beryllium (Be), aluminum (Al), barium (Ba), magnesium (Mg), calcium (Ca), strontium (Sr), titanium (Ti), zirconium (Zr), vanadium (V), yttrium (Y), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), gallium (Ga), indium (In), thallium (Tl), silicon (Si), germanium (Ge), lead (Pb), phosphorus (P), arsenic (As), lanthanum (La), cerium (Ce), gadolinium (Gd), neodymium (Nd), tellurium (Te), scandium (Sc), polonium (Po), praseodymium (Pr), terbium (Tb), dysprosium (Dy), holmium (Ho), europium (Eu), erbium (Er), ytterbium (Yb), antimony (Sb), bismuth (Bi), zinc (Zn), tin (Sn), and hafnium (Hf).

11. The method of claim 9, wherein the metal organic salt comprises at least one anion selected from hydroxide, acetate, propionate, acetylacetonate, 2,2,6,6-tetramethyl-3,5-heptanedionate, methoxide, sec-butoxide, t-butoxide, n-propoxide, i-propoxide, ethoxide, phosphate, alkylphosphonate, nitrate, perchlorate, sulfate, alkylsulfonate, phenoxide, fluoride, bromide, iodide, and chloride.

12. The method of claim 9, wherein the metal inorganic salt comprises at least one of zinc(II) acetate, tin(II) chloride, and hafnium(IV) chloride.

13. The method of claim 9, wherein coating the metal compound solution comprises spin coating, dip coating, bar coating, screen printing, slide coating, roll coating, spray coating, slot coating, dip-pen, inkjet, and nano-dispensing methods.

14. The method of claim 9, wherein the heat-treating of the metal compound solution is performed at a temperature in a range from about 100 to about 500° C.

15. The method of claim 9, wherein the metal compound solution further comprises a stabilizer.

16. The method of claim 15, wherein the stabilizer comprises at least one of diketone, amino alcohol, and polyamine.

17. The method of claim 16, wherein the diketone comprises acetylacetone.

18. The method of claim 16, wherein the amino alcohol comprises at least one of ethanolamine, diethanolamine, and triethanolamine.

19. The method of claim 16, wherein the polyamine comprises at least one of ethylenediamine and 1,4-diaminobutane.

20. The method of claim 9, wherein the solvent comprises at least one of water, tetrahydrofuran (THF), ether, and alcohol.
